(19) United States
(12) Patent Application Publication
(10) Pub. No.: US 2026/0101435 A1
(43) Pub. Date: Apr. 9, 2026

(54) WIRING CIRCUIT BOARD

(71) Applicant: NITTO DENKO CORPORATION, Osaka (JP)

(72) Inventors: Hayato TAKAKURA, Osaka (JP); Hiroki YAMAGUCHI, Osaka (JP); Tomoaki TANAKA, Osaka (JP)

(73) Assignee: NITTO DENKO CORPORATION, Osaka (JP)

(21) Appl. No.: 19/340,299

(22) Filed: Sep. 25, 2025

(30) Foreign Application Priority Data
Oct. 3, 2024 (JP) 2024-174429

(51) Int. Cl. H05K 1/02

(52) U.S. Cl. CPC H05K 1/0296

(57) ABSTRACT

A wiring circuit board includes a metal support board, an insulating layer disposed on one surface in a thickness direction of the metal support board, and a conductive pattern disposed on one surface in the thickness direction of the insulating layer. The conductive pattern includes a wiring, and the wiring includes a first wiring, a second wiring, and a third wiring. A thickness T2 of the second wiring is thicker than a thickness T1 of the first wiring, and a thickness T3 of the third wiring is thicker than the thickness T2 of the second wiring.

### CROSS-REFERENCE TO RELATED APPLICATION

The present application claims priority from Japanese Patent Application No. 2024-174429 filed on Oct. 3, 2024, the contents of which are hereby incorporated by reference into this application.

### TECHNICAL FIELD

The present invention relates to a wiring circuit board.

BACKGROUND ART

Conventionally, a wiring circuit board including a plurality of wiring bodies which are spaced from each other has been known (ref: for example, Patent Document 1).

In the wiring circuit board of Patent Document 1, in the plurality of wiring bodies, a conductive layer having the same thickness is provided.

### CITATION LIST

### Patent Document

Patent Document 1: Japanese Unexamined Patent Publication No. 2019-212656

### SUMMARY OF THE INVENTION

### Problem to be Solved by the Invention

On the other hand, in the wiring circuit board, by disposing the wiring having a different thickness in accordance with its application, an increase in a degree of freedom in wiring design is required.

The present invention provides a wiring circuit board capable of increasing a degree of freedom in wiring design.

### Means for Solving the Problem

The present invention [1] includes a wiring circuit board including a metal support board, an insulating layer disposed on one surface in a thickness direction of the metal support board, and a conductive pattern disposed on one surface in the thickness direction of the insulating layer, wherein the conductive pattern includes a wiring; the wiring includes a first wiring, a second wiring, and a third wiring; a thickness T2 of the second wiring is thicker than a thickness T1 of the first wiring; and a thickness T3 of the third wiring is thicker than the thickness T2 of the second wiring.

The present invention [2] includes the wiring circuit board described in the above-described [1], wherein the third wiring has a central portion and an end portion in a width direction perpendicular to the thickness direction and a direction in which the wiring extends, and the central portion protrudes toward one side in the thickness direction as compared with the end portion.

The present invention [3] includes the wiring circuit board described in the above-described [1] or [2], wherein the first wiring has a first conductive layer, the second wiring has a second conductive layer, and the third wiring has the first conductive layer and the second conductive layer covering the first conductive layer.

The present invention [4] includes the wiring circuit board described in any one of the above-described [1] to [3], wherein the conductive pattern further includes a terminal connected to the wiring.

The present invention [5] includes the wiring circuit board described in the above-described [4], wherein a thickness T4 of the terminal is thicker than the thickness T3 of the third wiring.

The present invention [6] includes the wiring circuit board described in the above-described [4] or [5], wherein the terminal has the first conductive layer and the second conductive layer disposed on one surface in the thickness direction of the first conductive layer.

The present invention [7] includes the wiring circuit board described in any one of the above-described [4] to [6] including a terminal disposition portion in which the terminal is disposed; a wiring portion in which at least one selected from the group consisting of the first wiring, the second wiring, and the third wiring is disposed; and a connecting portion connecting the terminal disposition portion to the wiring portion, wherein at least one selected from the group consisting of the first wiring, the second wiring, and the third wiring is disposed in the connecting portion.

The present invention [8] includes the wiring circuit board described in the above-described [7], wherein at least the third wiring is disposed in the connecting portion.

The present invention [9] includes the wiring circuit board described in the above-described [7] or [8], wherein the wiring portion includes at least a first wiring portion in which the first wiring is disposed and a third wiring portion in which the third wiring is disposed, and the first wiring portion and the third wiring portion are spaced from each other in the width direction perpendicular to the thickness direction and the direction in which the wiring extends.

### Effect of the Invention

The wiring circuit board of the present invention includes the first wiring, the second wiring, and the third wiring; the thickness T2 of the second wiring is thicker than the thickness T1 of the first wiring; and the thickness T3 of the third wiring is thicker than the thickness T2 of the second wiring. Therefore, it is possible to increase a degree of freedom in wiring design.

### BRIEF DESCRIPTION OF THE DRAWINGS

FIG. 1 shows a plan view of a wiring circuit board as one embodiment of the present invention.

FIG. 2 shows a bottom view of a wiring circuit board as one embodiment of the present invention.

FIG. 3 shows an A-A cross-sectional view of the wiring circuit board shown in FIG. 1.

FIG. 4 shows a B-B cross-sectional view of the wiring circuit board shown in FIG. 1.

FIGS. 5A and 5B show process views for illustrating a method for producing a wiring circuit board:

FIG. 5A illustrating an insulating layer (base insulating layer) forming step and FIG. 5B illustrating a first conductive layer forming step.

FIGS. 6A and 6B, subsequent to FIG. 5B, show process views for illustrating a method for producing a wiring circuit board:

FIG. 6A illustrating a second conductive layer forming step and

FIG. 6B illustrating a cover insulating layer forming step.

FIG. 7 shows a plan view of a modified example of a wiring circuit board.

FIG. 8 shows a C-C cross-sectional view of the modified example of the wiring circuit board shown in FIG. 7.

### DESCRIPTION OF EMBODIMENTS

### 1. Wiring Circuit Board

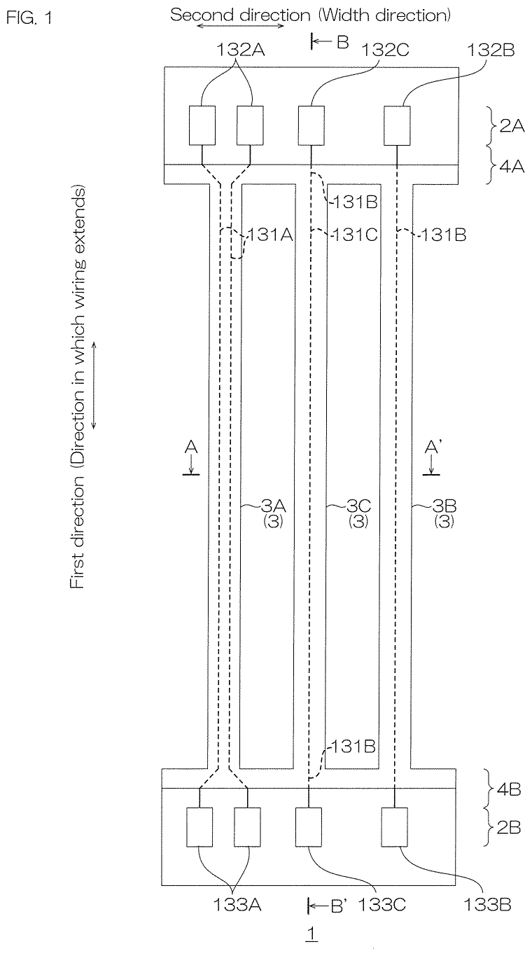

One embodiment of a wiring circuit board 1 is described with reference to FIGS. 1 to 4.

The wiring circuit board 1 includes a terminal disposition portion 2 in which terminals 132 and 133 are disposed; a wiring portion 3 in which at least one selected from the group consisting of a first wiring 131A, a second wiring 131B, and a third wiring 131C is disposed; and a connecting portion 4 connecting the terminal disposition portion 2 to the wiring portion 3. Specifically, as shown in FIG. 1, the wiring circuit board 1 includes a terminal disposition portion 2A in which terminals 132A, 132B, and 132C are disposed; a terminal disposition portion 2B in which terminals 133A, 133B, and 133C are disposed; a first wiring portion 3A in which the first wiring 131A is disposed; a second wiring portion 3B in which the second wiring 131B is disposed; a third wiring portion 3C in which the third wiring 131C is disposed; a connecting portion 4A connecting the terminal disposition portion 2A to the wiring portion 3; and a connecting portion 4B connecting the terminal disposition portion 2B to the wiring portion 3.

The wiring circuit board 1 includes the two terminal disposition portions 2A and 2B. The terminals 132A, 132B, and 132C of a conductive pattern 13 to be described later are disposed in the terminal disposition portion 2A. The terminals 133A, 133B, and 133C of the conductive pattern 13 to be described later are disposed in the terminal disposition portion 2B.

The terminal disposition portions 2A and 2B are spaced from each other in a first direction. The first direction is a direction in which the wiring 131 (the wiring portion 3) extends. The first direction (direction in which the wiring 131 extends) is perpendicular to a thickness direction of the wiring circuit board 1. Each of the terminal disposition portions 2A and 2B extends in a second direction. The second direction is a width direction of the wiring 131 (the wiring portion 3). The second direction (width direction) is perpendicular to both the thickness direction and the first direction.

The wiring circuit board 1 includes the plurality of wiring portions 3. At least one selected from the group consisting of the first wiring 131A of the conductive pattern 13 to be described later, the second wiring 131B of the conductive pattern 13 to be described later, and the third wiring 131C of the conductive pattern 13 to be described later is disposed in the wiring portion 3. In other words, the wiring portion 3 includes at least one selected from the group consisting of the first wiring portion 3A in which the first wiring 131A is disposed, the second wiring portion 3B in which the second wiring 131B is disposed, and the third wiring portion 3C in which the third wiring 131C is disposed. The wiring portion 3 preferably includes at least the first wiring portion 3A in which the first wiring 131A is disposed, and the third wiring portion 3C in which the third wiring 131C is disposed.

In the wiring circuit board 1 shown in FIG. 1, the plurality of wiring portions 3 include the first wiring portion 3A, the second wiring portion 3B, and the third wiring portion 3C.

Each of the first wiring portion 3A, the second wiring portion 3B, and the third wiring portion 3C is disposed between the terminal disposition portion 2A and the terminal disposition portion 2B in the first direction. In the present embodiment, each of the first wiring portion 3A, the second wiring portion 3B, and the third wiring portion 3C extends in the first direction. One end portion in the first direction of each of the first wiring portion 3A, the second wiring portion 3B, and the third wiring portion 3C is connected to the terminal disposition portion 2A via the connecting portion 4A. The other end portion in the first direction of each of the first wiring portion 3A, the second wiring portion 3B, and the third wiring portion 3C is connected to the terminal disposition portion 2B via the connecting portion 4B. A shape of each of the first wiring portion 3A, the second wiring portion 3B, and the third wiring portion 3C is not limited, and may be a linear shape or a curved shape.

The first wiring portion 3A, the second wiring portion 3B, and the third wiring portion 3C are disposed along the second direction. In other words, the first wiring portion 3A, the second wiring portion 3B, and the third wiring portion 3C are disposed along the width direction perpendicular to the direction in which the wiring 131 extends. The first wiring portion 3A, the second wiring portion 3B, and the third wiring portion 3C are spaced from each other in the second direction. In other words, the first wiring portion 3A, the second wiring portion 3B, and the third wiring portion 3C are spaced from each other in the width direction perpendicular to the direction in which the wiring 131 extends.

In the second direction, the order in which the first wiring portion 3A, the second wiring portion 3B, and the third wiring portion 3C are disposed is not particularly limited. In FIG. 1, in the second direction, the first wiring portion 3A, the third wiring portion 3C, and the second wiring portion 3B are disposed in this order. That is, the first wiring portion 3A and the third wiring portion 3C are spaced from each other in the second direction, and the third wiring portion 3C and the second wiring portion 3B are spaced from each other in the second direction. In other words, the first wiring portion 3A and the third wiring portion 3C are spaced from each other in the width direction perpendicular to the direction in which the wiring 131 (the wiring portion 3) extends, and the third wiring portion 3C and the second wiring portion 3B are spaced from each other in the width direction perpendicular to the direction in which the wiring 131 (the wiring portion 3) extends.

A width of each of the first wiring portion 3A, the second wiring portion 3B, and the third wiring portion 3C is, for example, 10 μm to 300 μm, preferably 50 μm to 250 μm. The width of each of the first wiring portion 3A, the second wiring portion 3B, and the third wiring portion 3C may be the same or may be different from each other.

The “width” is the maximum length in the width direction perpendicular to both the direction in which the wiring 131 (the wiring portion 3) extends and the thickness direction. For example, the “width” of the first wiring portion 3A is the maximum length in the width direction perpendicular to both the direction in which the first wiring portion 3A extends and the thickness direction. In the present embodiment, the “width” is the maximum length in the second direction.

In the second direction, an interval between the wiring portions 3 adjacent to each other is, for example, 5 μm to 300 μm, preferably 10 μm to 250 μm. The interval between the wiring portions 3 adjacent to each other may be the same or may be different from each other.

In the second direction, the interval between the wiring portions 3 adjacent to each other is, for example, the interval between the first wiring portion 3A and the third wiring portion 3C, and the interval between the third wiring portion 3C and the second wiring portion 3B.

The wiring circuit board 1 includes the two connecting portions 4A and 4B.

The connecting portion 4A is disposed between the terminal disposition portion 2A and the wiring portion 3. The connecting portion 4A connects the terminal disposition portion 2A to the wiring portion 3.

Th connecting portion 4B is disposed between the terminal disposition portion 2B and the wiring portion 3. The connecting portion 4B connects the terminal disposition portion 2B to the wiring portion 3.

The connecting portions 4A and 4B are spaced from each other in the first direction. Each of the connecting portions 4A and 4B extends in the second direction.

At least one selected from the group consisting of the first wiring 131A of the conductive pattern 13 to be described later, the second wiring 131B of the conductive pattern 13 to be described later, and the third wiring 131C of the conductive pattern 13 to be described later is disposed in each of the connecting portions 4A and 4B.

In the wiring circuit board 1 shown in FIG. 1, though the details are described later, the terminal 132A and the terminal 133A are connected by the single first wiring 131A. The terminal 132B and the terminal 133B are connected by the single second wiring 131B. The terminal 132C and the terminal 133C are connected by a composite wiring consisting of the second wiring 131B and the third wiring 131C.

In the present embodiment, in each of the connecting portions 4A and 4B, the first wiring 131A is disposed between the terminal disposition portions 2A and 2B, and the first wiring portion 3A. That is, the single first wiring 131A is disposed continuously to the connecting portion 4A, the first wiring portion 3A, and the connecting portion 4B between the terminal 132A and the terminal 133A, and connects the terminal 132A to the terminal 133A.

In the present embodiment, in each of the connecting portions 4A and 4B, the second wiring 131B is disposed between the terminal disposition portions 2A and 2B, and the second wiring portion 3B. That is, the single second wiring 131B is disposed continuously to the connecting portion 4A, the second wiring portion 3B, and the connecting portion 4B between the terminal 132B and the terminal 133B, and connects the terminal 132B to the terminal 133B.

In the present embodiment, in each of the connecting portions 4A and 4B, the second wiring 131B is disposed between the terminal disposition portions 2A and 2B, and the third wiring portion 3C. That is, the composite wiring consisting of the second wiring 131B and the third wiring 131C is disposed continuously to the connecting portion 4A, the third wiring portion 3C, and the connecting portion 4B between the terminal 132C and the terminal 133C, and connects the terminal 132C to the terminal 133C. The composite wiring consists of the second wiring 131B disposed in the connecting portion 4A, the third wiring 131C disposed in the third wiring portion 3C, and the second wiring 131B disposed in the connecting portion 4B. In the composite wiring, though the details are described later, a second conductive layer 1312 provided in the second wiring 131B and the second conductive layer 1312 provided in the third wiring 131C are continuous, and the second wiring 131B and the third wiring 131C are electrically connected to each other.

That is, in the present embodiment, the first wiring 131A and the second wiring 131B are disposed in each of the connecting portions 4A and 4B, and the third wiring 131C is not disposed.

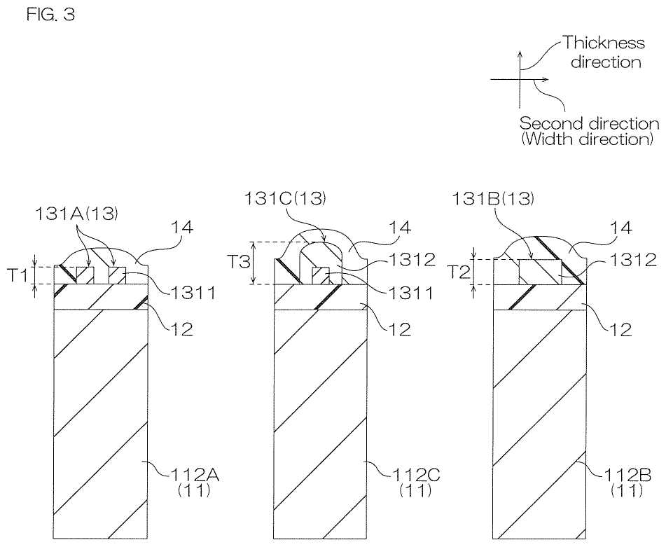

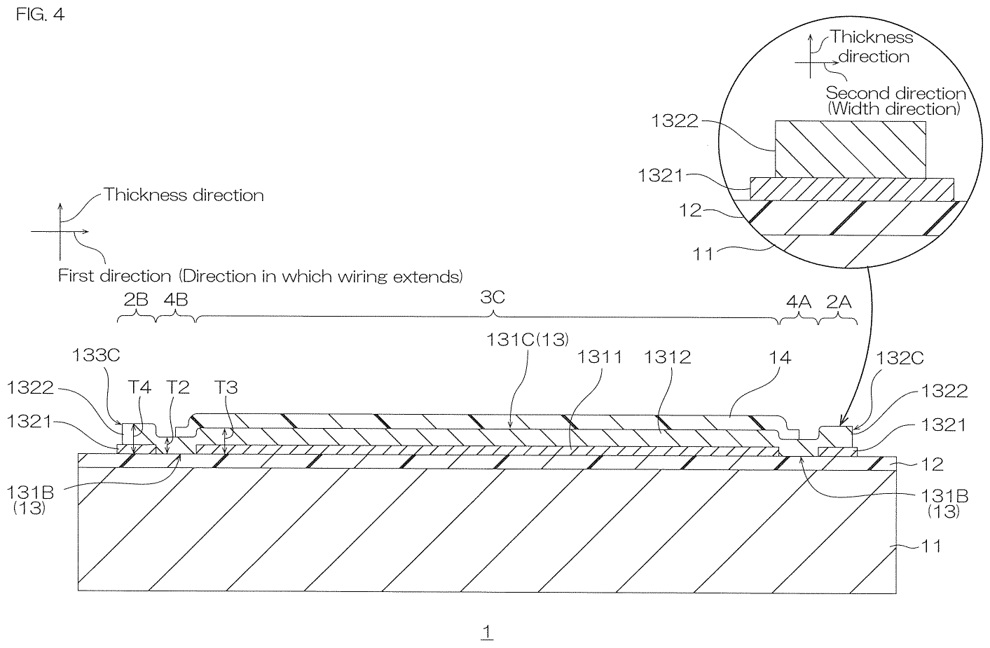

As shown in FIGS. 3 and 4, the wiring circuit board 1 includes a metal support board 11, an insulating layer 12 (base insulating layer), and the conductive pattern 13. Further, the wiring circuit board 1 further includes a cover insulating layer 14, if necessary.

### (1) Metal Support Board

The metal support board 11 supports the insulating layer 12, the conductive pattern 13, and the cover insulating layer 14. The metal support board 11 is made of a metal. Examples of a material for the metal support board 11 include copper, nickel, cobalt, iron, and alloys of these. Examples of the alloy include copper alloys. As the material for the metal support board 11, preferably, a copper alloy is used.

A thickness of the metal support board 11 is, for example, 10 μm to 300 μm, preferably 50 μm to 250 μm.

As shown in FIGS. 1 and 3, the metal support board 11 has two terminal support portions 111A and 111B and a plurality of wiring support portions 112A, 112B, and 112C.

The terminal support portion 111A is the metal support board 11 of the terminal disposition portion 2A and the connecting portion 4A. The terminal support portion 111A supports at least one of the terminals 132A, 132B, and 132C of the conductive pattern 13 disposed in the terminal disposition portion 2A, the first wiring 131A of the conductive pattern 13 disposed in the connecting portion 4A, the second wiring 131B of the conductive pattern 13, and the third wiring 131C of the conductive pattern 13.

The terminal support portion 111B is the metal support board 11 of the terminal disposition portion 2B and the connecting portion 4B. The terminal support portion 111B is spaced from the terminal support portion 111A in the first direction. The terminal support portion 111B supports at least one of the terminals 133A, 133B, and 133C of the conductive pattern 13 disposed in the terminal disposition portion 2B, the first wiring 131A of the conductive pattern 13 disposed in the connecting portion 4B, the second wiring 131B of the conductive pattern 13, and the third wiring 131C of the conductive pattern 13.

The wiring support portion 112A is the metal support board 11 of the first wiring portion 3A. The wiring support portion 112A is disposed between the terminal support portion 111A and the terminal support portion 111B in the first direction. The wiring support portion 112A supports the first wiring 131A. The wiring support portion 112A extends along the first wiring 131A in the first direction. One end portion in the first direction of the wiring support portion 112A is connected to the terminal support portion 111A. The other end portion in the first direction of the wiring support portion 112A is connected to the terminal support portion 111B.

The wiring support portion 112B is the metal support board 11 of the second wiring portion 3B. The wiring support portion 112B is disposed between the terminal support portion 111A and the terminal support portion 111B in the first direction. The wiring support portion 112B supports the second wiring 131B. The wiring support portion 112B extends along the second wiring 131B in the first direction. One end portion in the first direction of the wiring support portion 112B is connected to the terminal support portion 111A. The other end portion in the first direction of the wiring support portion 112B is connected to the terminal support portion 111B.

The wiring support portion 112C is the metal support board 11 of the third wiring portion 3C. The wiring support portion 112C is disposed between the terminal support portion 111A and the terminal support portion 111B in the first direction. The wiring support portion 112C supports the third wiring 131C. The wiring support portion 112C extends along the third wiring 131C in the first direction. One end portion in the first direction of the wiring support portion 112C is connected to the terminal support portion 111A. The other end portion in the first direction of the wiring support portion 112C is connected to the terminal support portion 111B.

The wiring support portions 112A, 112B, and 112C are disposed along the second direction. The wiring support portions 112A, 112B, and 112C are spaced from each other in the second direction.

The width of the wiring support portion 112A is, for example, 5 μm to 300 μm, preferably 10 μm to 250 μm. The width of the wiring support portion 112A may be the same or may be different from the width of the first wiring portion 3A.

A ratio (thickness/width) of the thickness of the wiring support portion 112A to the width of the wiring support portion 112A is, for example, 2 or more, preferably 5 or more, and for example, 30 or less, preferably 10 or less. Hereinafter, the ratio (thickness/width) of the thickness of the wiring support portion to the width of the wiring support portion is defined as an aspect ratio of the wiring support portion.

When the aspect ratio of the wiring support portion 112A is the above-described lower limit value or more, the first wiring portion 3A is easily deformable in the width direction as compared with the thickness direction. Further, it is possible to ensure the rigidity of the first wiring portion 3A in the thickness direction.

The width and the aspect ratio of the wiring support portion 112B and the wiring support portion 112C are also appropriately adjusted within the range described in the width and the aspect ratio of the wiring support portion 112A described above.

That is, when the aspect ratio of the wiring support portion 112B is the above-described lower limit value or more, the second wiring portion 3B is easily deformable in the width direction as compared with the thickness direction. Further, it is possible to ensure the rigidity of the second wiring portion 3B in the thickness direction. Furthermore, when the aspect ratio of the wiring support portion 112C is the above-described lower limit value or more, the third wiring portion 3C is easily deformable in the width direction as compared with the thickness direction. Further, it is possible to ensure the rigidity of the third wiring portion 3C in the thickness direction.

The width and the aspect ratio of the wiring support portions 112A, 112B, and 112C may be the same or may be different from each other.

In the second direction, the interval between the wiring support portion 112A and the wiring support portion 112C, and the interval between the wiring support portion 112C and the wiring support portion 112B are, for example, 5 μm to 300 μm, preferably 10 μm to 250 μm. In the second direction, the interval between the wiring support portion 112A and the wiring support portion 112C, and the interval between the wiring support portion 112C and the wiring support portion 112B may be the same or may be different from each other.

### (2) Insulating Layer

As shown in FIGS. 3 and 4, the insulating layer 12 (base insulating layer) is disposed on one surface in the thickness direction of the metal support board 11. In other words, the insulating layer 12 is in contact with one surface in the thickness direction of the metal support board 11. The insulating layer 12 is disposed between the metal support board 11 and the conductive pattern 13 in the thickness direction. The insulating layer 12 insulates the metal support board 11 from the conductive pattern 13. The insulating layer 12 is made of a resin. Examples of the resin include polyimide, maleimide, epoxy resins, polybenzoxazole, and polyester. Preferably, polyimide is used.

The thickness of the insulating layer 12 is, for example, 1 μm or more, preferably 5 μm or more, and for example, 100 μm or less, preferably 50 μm or less.

### (3) Conductive Pattern

As shown in FIGS. 3 and 4, the conductive pattern 13 is disposed on one surface in the thickness direction of the insulating layer 12 (base insulating layer). In other words, the conductive pattern 13 is in contact with one surface in the thickness direction of the insulating layer 12. The conductive pattern 13 is disposed at the opposite side of the metal support board 11 in the thickness direction with respect to the insulating layer 12. The shape of the conductive pattern 13 is not limited.

The conductive pattern 13 includes the plurality of wirings 131. The conductive pattern 13 preferably furthermore includes the plurality of terminals 132 and 133 connected to the wiring 131.

The plurality of terminals 132A, 132B, and 132C are disposed in the terminal disposition portion 2A. The plurality of terminals 132A, 132B, and 132C are disposed along the second direction. The plurality of terminals 132A, 132B, and 132C are spaced from each other in the second direction.

The plurality of terminals 133A, 133B, and 133C are disposed in the terminal disposition portion 2B. The plurality of terminals 133A, 133B, and 133C are disposed along the second direction. The plurality of terminals 133A, 133B, and 133C are spaced from each other in the second direction.

Each of the plurality of terminals 132 and 133 has a square land shape.

The wiring 131 includes the first wiring 131A, the second wiring 131B, and the third wiring 131C. Examples of the wiring 131 include signal wirings (for example, differential wirings), power supply wirings, ground lines, and antenna lines.

Although the details are described later, each of the first wiring 131A, the second wiring 131B, and the third wiring 131C has the different thickness. Therefore, it is possible to appropriately select the wiring to be used in accordance with a function and a placement location of the wiring.

At least a portion of the first wiring 131A is disposed in the first wiring portion 3A. In the present embodiment, the first wiring 131A is disposed continuously to the connecting portion 4A, the first wiring portion 3A, and the connecting portion 4B, and electrically connects the terminal 132A to the terminal 133A. One end portion in the first direction of the first wiring 131A is connected to the terminal 132A. The other end portion in the first direction of the first wiring 131A is connected to the terminal 133A.

As shown in FIG. 1, in the present embodiment, the two first wirings 131A are disposed in the connecting portions 4A and 4B and the first wiring portion 3A. The first wiring 131A is, for example, a signal wiring (for example, differential wiring).

At least a portion of the second wiring 131B is disposed in the second wiring portion 3B. In the present embodiment, the second wiring 131B is disposed continuously to the connecting portion 4A, the second wiring portion 3B, and the connecting portion 4B, and electrically connects the terminal 132B to the terminal 133B. One end portion in the first direction of the second wiring 131B is connected to the terminal 132B. The other end portion in the first direction of the second wiring 131B is connected to the terminal 133B.

As shown in FIG. 1, in the present embodiment, the one second wiring 131B is disposed in the connecting portions 4A and 4B and the second wiring portion 3B. The second wiring 131B is, for example, the power supply wiring.

At least a portion of the third wiring 131C is disposed in the third wiring portion 3C. In the present embodiment, the third wiring 131C is disposed in the third wiring portion 3C, and forms the composite wiring along with the second wiring 131B disposed in the connecting portions 4A and 4B. The composite wiring consisting of the second wiring 131B and the third wiring 131C electrically connects the terminal 132C to the terminal 133C. One end portion in the first direction of the composite wiring is connected to the terminal 132C. The other end portion in the first direction of the composite wiring is connected to the terminal 133C.

As shown in FIG. 1, in the present embodiment, the one composite wiring consisting of the second wiring 131B and the third wiring 131C is disposed in the connecting portions 4A and 4B and the third wiring portion 3C. The composite wiring consisting of the second wiring 131B and the third wiring 131C is, for example, the power supply wiring.

The first wiring 131A, the second wiring 131B, and the third wiring 131C (composite wiring consisting of the second wiring 131B and the third wiring 131C) are disposed along the second direction. The first wiring 131A, the second wiring 131B, and the third wiring 131C are spaced from each other in the second direction.

### (6) Cover Insulating Layer

The cover insulating layer 14 covers the entire wiring 131 in the wiring portion 3. Specifically, as shown in FIG. 1, the cover insulating layer 14 covers the first wiring 131A disposed in the first wiring portion 3A, the second wiring 131B disposed in the second wiring portion 3B, and the third wiring 131C disposed in the third wiring portion 3C. Further, the cover insulating layer 14 may cover at least a portion of the first wiring 131A, the second wiring 131B, and the third wiring 131C which are disposed in the connecting portions 4A and 4B.

As shown in FIGS. 1 and 4, the cover insulating layer 14 does not cover the terminals 132 and 133. Further, the cover insulating layer 14 may not cover at least a portion of the first wiring 131A, the second wiring 131B, and the third wiring 131C which are disposed in the connecting portions 4A and 4B.

The cover insulating layer 14 is disposed at one side in the thickness direction of the insulating layer 12 (base insulating layer). The cover insulating layer 14 is made of the resin. Examples of the resin include polyimide, maleimide, epoxy resins, polybenzoxazole, and polyester. Preferably, polyimide is used.

### 2. Details of Wiring and Terminal

The details of the first wiring 131A, the second wiring 131B, the third wiring 131C, and the terminals 132 and 133 are described with reference to FIG. 3.

### (1) First Wiring

As shown in FIG. 3, the first wiring 131A has a generally rectangular shape in a cross-sectional view. One surface in the thickness direction of the first wiring 131A is flat. Both side surfaces of the first wiring 131A in the width direction are flat surfaces extending in the thickness direction.

“One surface in the thickness direction of the first wiring 131A is flat” means that a difference between the maximum thickness and the minimum thickness of the first wiring 131A is 5% or less of the maximum thickness. In other words, unavoidable surface unevenness generated in a production process is acceptable.

A thickness T1 of the first wiring 131A is thinner than a thickness T2 of the second wiring 131B to be described later. Further, the thickness T1 of the first wiring 131A is thinner than a thickness T3 of the third wiring 131C to be described later. Furthermore, the thickness T1 of the first wiring 131A is thinner than a thickness T4 of the terminals 132 and 133 to be described later. That is, the thickness T1 of the first wiring 131A is the thinnest among the thickness T1 of the first wiring 131A, the thickness T2 of the second wiring 131B, the thickness T3 of the third wiring 131C, and the thickness T4 of the terminals 132 and 133.

The thickness T1 of the first wiring 131A, the thickness T2 of the second wiring 131B, the thickness T3 of the third wiring 131C, and the thickness T4 of the terminals 132 and 133 indicate the maximum length from the other surface in the thickness direction to one surface in the thickness direction of each of these.

The thickness T1 of the first wiring 131A is, for example, 1 μm or more, preferably 5 μm or more, and for example, 50 μm or less, preferably 30 μm or less.

The width of the first wiring 131A is, for example, 1 μm or more, preferably 5 μm or more, and for example, 50 μm or less, preferably 30 μm or less. The width of the first wiring 131A is preferably smaller than the width of the second wiring 131B to be described later, and also smaller than the width of the third wiring 131C to be described later.

The first wiring 131A has a first conductive layer 1311. The first wiring 131A does not have a second conductive layer 1312. In the present embodiment, the first wiring 131A consists of a seed layer (not shown) to be described later and the first conductive layer 1311.

The first conductive layer 1311 of the first wiring 131A is made of the metal. Examples of the metal include copper, silver, gold, iron, aluminum, chromium, and alloys of these. In order to obtain excellent electrical properties, as the metal, preferably, copper is used.

The first conductive layer 1311 of the first wiring 131A is disposed at one side in the thickness direction of the insulating layer 12. In the present embodiment, the first conductive layer 1311 of the first wiring 131A is connected to the terminal 132A and the terminal 133A. Specifically, the first conductive layer 1311 of the first wiring 131A is preferably continuous to the first conductive layer 1321 of the terminal 132A and the first conductive layer 1321 of the terminal 133A to be described later. That is, the first conductive layer 1311 of the first wiring 131A is preferably made of the same metal as the first conductive layer 1321 of the terminal 132A and the first conductive layer 1321 of the terminal 133A to be described later.

### (2) Second Wiring

As shown in FIG. 3, the second wiring 131B has the generally rectangular shape in the cross-sectional view. One surface in the thickness direction of the second wiring 131B is flat. Both side surfaces of the second wiring 131B in the width direction are the flat surfaces extending in the thickness direction.

“One surface in the thickness direction of the second wiring 131B is flat” means that the difference between the maximum thickness and the minimum thickness of the second wiring 131B is 5% or less of the maximum thickness. In other words, the unavoidable surface unevenness generated in the production process is acceptable.

The thickness T2 of the second wiring 131B is thicker than the thickness T1 of the first wiring 131A. Further, the thickness T2 of the second wiring 131B is thinner than the thickness T3 of the third wiring 131C to be described later. Furthermore, the thickness T2 of the second wiring 131B is thinner than the thickness T4 of the terminals 132 and 133 to be described later.

The thickness T2 of the second wiring 131B is, for example, 5 μm or more, preferably 10 μm or more, and for example, 100 μm or less, preferably 50 μm or less.

The difference (T2-T1) between the thickness T2 of the second wiring 131B and the thickness T1 of the first wiring 131A is, for example, 3 μm or more, preferably 5 μm or more, and for example, 50 μm or less, preferably 30 μm or less.

The width of the second wiring 131B is, for example, 5 μm or more, preferably 10 μm or more, and for example, 100 μm or less, preferably 50 μm or less. The width of the second wiring 131B is preferably larger than the width of the first wiring 131A, and also smaller than the width of the third wiring 131C to be described later.

The second wiring 131B has the second conductive layer 1312. The second wiring 131B does not have the first conductive layer 1311. In the present embodiment, the second wiring 131B consists of the seed layer (not shown) to be described later and the second conductive layer 1312.

The second conductive layer 1312 of the second wiring 131B is made of the metal. Examples of the metal include copper, silver, gold, iron, aluminum, chromium, and alloys of these. In order to obtain the excellent electrical properties, as the metal, preferably, copper is used.

The second conductive layer 1312 of the second wiring 131B is disposed at one side in the thickness direction of the insulating layer 12. In the present embodiment, the second conductive layer 1312 of the second wiring 131B is connected to the terminal 132B and the terminal 133B. Specifically, the second conductive layer 1312 of the second wiring 131B is preferably continuous to a second conductive layer 1322 of the terminal 132B and the second conductive layer 1322 of the terminal 133B to be described later. That is, the second conductive layer 1312 of the second wiring 131B is preferably made of the same metal as the second conductive layer 1322 of the terminal 133A and the second conductive layer 1322 of the terminal 133B to be described later.

### (3) Third Wiring

As shown in FIG. 3, the third wiring 131C has an arched shape in the cross-sectional view (inverted U-shape in the cross-sectional view). The third wiring 131C has a central portion (central portion in the width direction) and an end portion (end portion in the width direction) in the width direction. The central portion is disposed in the center of the third wiring 131C in the width direction. The end portion is disposed at the end of the third wiring 131C in the width direction. In the width direction, the central portion protrudes toward one side in the thickness direction as compared with the end portion. In other words, in the width direction, the central portion protrudes toward the opposite side of the metal support board 11 with respect to the insulating layer 12 in the thickness direction as compared with the end portion. One surface in the thickness direction of the third wiring 131C has a generally circular arc shape. Both side surfaces of the third wiring 131C in the width direction are the flat surfaces extending in the thickness direction.

Since the central portion in the width direction of the third wiring 131C protrudes toward one side in the thickness direction as compared with the end portion in the width direction of the third wiring 131C, it is possible to increase the rigidity of the third wiring 131C in the thickness direction, while suppressing an increase in the rigidity of the third wiring 131C in the width direction. As a result, it is possible to increase the rigidity of the third wiring portion 3C in the thickness direction so as not to hinder deformation of the third wiring portion 3C in the width direction.

A percentage ((difference between the thickness of the central portion and the thickness of the end portion)/thickness of the central portion×100) of the difference between the thickness of the central portion in the width direction of the third wiring 131C and the thickness of the end portion in the width direction of the third wiring 131C with respect to the thickness of the central portion in the width direction of the third wiring 131C is, for example, 10% or more, preferably 20% or more, more preferably 25% or more, and for example, 70% or less, preferably 60% or less, more preferably 55% or less. The percentage ((difference between the thickness of the central portion and the thickness of the end portion)/thickness of the central portion×100) of the difference between the thickness of the central portion in the width direction of the third wiring 131C and the thickness of the end portion in the width direction of the third wiring 131C with respect to the thickness of the central portion in the width direction of the third wiring 131C is defined as a protrusion ratio of the central portion in the width direction of the third wiring 131C.

When the protrusion ratio of the central portion in the width direction of the third wiring 131C is the above-described lower limit value or more, it is possible to reliably increase the rigidity of the wiring in the thickness direction. When the protrusion ratio of the central portion in the width direction of the third wiring 131C is the above-described upper limit value or less, it is possible to ensure the wiring cross-sectional area, and reduce electric resistivity of the third wiring 131C.

The thickness T3 of the third wiring 131C is thicker than the thickness T1 of the first wiring 131A. Further, the thickness T3 of the third wiring 131C is thicker than the thickness T2 of the second wiring 131B. Furthermore, the thickness T3 of the third wiring 131C is thinner than the thickness T4 of the terminals 132 and 133 to be described later.

The thickness T3 of the third wiring 131C is, as described above, the maximum length from the other surface in the thickness direction to one surface in the thickness direction of the third wiring 131C. That is, the thickness T3 of the third wiring 131C is the thickness of the third wiring 131C in the central portion in the width direction.

The thickness T3 of the third wiring 131C is, for example, 10 μm or more, preferably 30 μm or more, and for example, 150 μm or less, preferably 100 μm or less.

The difference (T3-T1) between the thickness T3 of the third wiring 131C and the thickness T1 of the first wiring 131A is, for example, 5 μm or more, preferably 10 μm or more, and for example, 100 μm or less, preferably 50 μm or less.

The difference (T3-T2) between the thickness T3 of the third wiring 131C and the thickness T2 of the second wiring 131B is, for example, 5 μm or more, preferably 10 μm or more, and for example, 50 μm or less, preferably 30 μm or less.

The ratio (thickness/width) of the thickness T3 of the third wiring 131C to the width of the third wiring 131C is, for example, 3.0 or less, preferably 2.0 or less, more preferably 1.7 or less, further more preferably 1.3 or less. Hereinafter, the ratio (thickness/width) of the thickness T2 of the third wiring 131C to the width of the third wiring 131C is defined as the aspect ratio of the third wiring 131C.

When the aspect ratio of the third wiring 131C is the above-described upper limit value or less, it is possible to suppress the excessive increase in the rigidity of the third wiring 131C in the thickness direction.

The aspect ratio of the third wiring 131C is, for example, 0.1 or more, preferably 0.3 or more, more preferably 0.5 or more, further more preferably 0.8 or more.

The width of the third wiring 131C is appropriately adjusted within the range which satisfies the aspect ratio of the third wiring 131C described above. The width of the third wiring 131C is preferably larger than the width of the first wiring 131A, and also larger than the width of the second wiring 131B. The width of the third wiring 131C is, for example, 10 μm or more, preferably 30 μm or more, and for example, 300 μm or less, preferably 200 μm or less. Further, the wiring cross-sectional area of the third wiring 131C is preferably larger than the wiring cross-sectional area of the first wiring 131A, and also larger than the wiring cross-sectional area of the second wiring 131B. Since the wiring circuit board 1 includes the third wiring 131C having the relatively large wiring cross-sectional area, it is possible to reduce the electric resistivity.

The third wiring 131C has the first conductive layer 1311 and the second conductive layer 1312 covering the first conductive layer 1311. In the present embodiment, the third wiring 131C consists of the seed layer (not shown), the first conductive layer 1311, and the second conductive layer 1312 covering the first conductive layer 1311.

The first conductive layer 1311 of the third wiring 131C is made of the same metal as the first conductive layer 1311 of the first wiring 131A described above.

The first conductive layer 1311 of the third wiring 131C is disposed at one side in the thickness direction of the insulating layer 12. The first conductive layer 1311 of the third wiring 131C is disposed in the central portion in the width direction of the third wiring 131C. The first conductive layer 1311 of the third wiring 131C has the generally rectangular shape in the cross-sectional view.

The width of the first conductive layer 1311 of the third wiring 131C is smaller than the width (total width) of the third wiring 131C. The width of the first conductive layer 1311 of the third wiring 131C is, for example, 1 μm or more, preferably 5 μm or more, and for example, 50 μm or less, preferably 30 μm or less.

The thickness of the first conductive layer 1311 of the third wiring 131C is thinner than the thickness T3 of the third wiring 131C. The thickness of the first conductive layer 1311 of the third wiring 131C is, for example, 1 μm or more, preferably 5 μm or more, and for example, 50 μm or less, preferably 30 μm or less.

The second conductive layer 1312 of the third wiring 131C is made of the same metal as the second conductive layer 1312 of the second wiring 131B described above.

The second conductive layer 1312 of the third wiring 131C is disposed at one side in the thickness direction of the insulating layer 12, and covers one surface in the thickness direction and both side surfaces in the width direction of the first conductive layer 1311 of the third wiring 131C. The second conductive layer 1312 of the third wiring 131C forms one surface in the thickness direction and both side surfaces in the width direction of the third wiring 131C.

The width of the second conductive layer 1312 of the third wiring 131C is the same as the width (total width) of the third wiring 131C. Further, the width of the second conductive layer 1312 of the third wiring 131C is larger than the width of the first conductive layer 1311 of the third wiring 131C. The width of the second conductive layer 1312 of the third wiring 131C is, for example, 3 μm or more, preferably 10 μm or more, and for example, 100 μm or less, preferably 75 μm or less.

The thickness of the second conductive layer 1312 of the third wiring 131C is thinner than the thickness T3 of the third wiring 131C. The thickness of the second conductive layer 1312 of the third wiring 131C is, for example, 5 μm or more, preferably 10 μm or more, and for example, 100 μm or less, preferably 50 μm or less.

In the portion where the first conductive layer 1311 of the third wiring 131C is present, the thickness of the second conductive layer 1312 of the third wiring 131C is the difference between the length from one surface in the thickness direction to the other surface in the thickness direction of the third wiring 131C and the thickness of the first conductive layer 1311 of the third wiring 131C. And, in the portion where the first conductive layer 1311 of the third wiring 131C is not present, the thickness of the second conductive layer 1312 of the third wiring 131C is the length from one surface in the thickness direction to the other surface in the thickness direction of the third wiring 131C.

A thickness ratio of the second conductive layer 1312 to the first conductive layer 1311 in the central portion in the width direction of the third wiring 131C is, for example, 1 or more, preferably 2 or more, and for example, 10 or less, preferably 5 or less.

In the present embodiment, as shown in FIGS. 1 and 4, the composite wiring consisting of the second wiring 131B and the third wiring 131C connects the terminal 132C to the terminal 133C. In the composite wiring, the second conductive layer 1312 of the third wiring 131C is continuous to the second conductive layer of the second wiring 131B. Then, the second conductive layer 1312 of the composite wiring (the second conductive layer 1312 continuous by the second wiring 131B and the third wiring 131C) is continuous to the second conductive layer 1322 of the terminal 132C to be described later and the second conductive layer 1322 of the terminal 133C. Further, in the present embodiment, the first conductive layer 1311 of the third wiring 131C is not continuous to the first conductive layer 1321 of the terminal 132C and the first conductive layer 1321 of the terminal 133C to be described later. The first conductive layer 1311 of the third wiring 131C is preferably made of the same metal as the first conductive layer 1321 of the terminal 132C and the first conductive layer 1321 of the terminal 133C to be described later, and the second conductive layer 1312 of the third wiring 131C is preferably made of the same metal as the second conductive layer 1322 of the terminal 132C and the second conductive layer 1322 of the terminal 133C to be described later.

(4) Terminal

The shape in the cross-sectional view (not shown) of the terminals 132 (132A, 132B, 132C) and 133 (133A, 133B, 133C) is not particularly limited as long as it has the first conductive layer 1321 to be described later and the second conductive layer 1322 disposed on one surface in the thickness direction of the first conductive layer 1321. As the shape in the cross-sectional view of the terminals 132 and 133, for example, when the width of the first conductive layer 1321 provided in the terminals 132 and 133 to be described later and the width of the second conductive layer 1322 are the same, it is the generally rectangular shape. Further, when the width of the first conductive layer 1321 provided in the terminals 132 and 133 to be described later is larger than the width of the second conductive layer 1322, it is a generally convex shape (shape in which the generally rectangular-shaped second conductive layer 1322 is stacked on one surface in the thickness direction of the generally rectangular-shaped first conductive layer 1321).

The thickness T4 of the terminals 132 and 133 is thicker than the thickness T1 of the first wiring 131A. Further, the thickness T4 of the terminal 132 is thicker than the thickness T2 of the second wiring 131B. Further, the thickness T4 of the terminals 132 and 133 is thicker than the thickness T3 of the third wiring 131C. That is, the thickness T4 of the terminals 132 and 133 is the thickest among the thickness T1 of the first wiring 131A, the thickness T2 of the second wiring 131B, the thickness T3 of the third wiring 131C, and the thickness T4 of the terminals 132 and 133.

The thickness T4 of the terminals 132 and 133 is, for example, 15 μm or more, preferably 40 μm or more, and for example, 500 μm or less, preferably 300 μm or less. The thickness T4 of the terminals 132 and 133 is the total thickness of the first conductive layer 1321 of the terminals 132 and 133 to be described later and the second conductive layer 1322 of the terminal 132. Each of the terminals 132A, 132B, 132C, 133A, 133B, and 133C has the same thickness.

The difference (T4-T1) between the thickness T4 of the terminals 132 and 133 and the thickness T1 of the first wiring 131A is, for example, 5 μm or more, preferably 10 μm or more, and for example, 100 μm or less, preferably 50 μm or less. The difference (T4-T1) between the thickness T4 of the terminals 132 and 133 and the thickness T1 of the first wiring 131A is the same as the thickness of the second conductive layer 1322 of the terminals 132 and 133 to be described later.

The difference (T4-T2) between the thickness T4 of the terminals 132 and 133 and the thickness T2 of the second wiring 131B is, for example, 1 μm or more, preferably 5 μm or more, and for example, 50 μm or less, preferably 30 μm or less. The difference (T4-T2) between the thickness T4 of the terminals 132 and 133 and the thickness T2 of the second wiring 131B is the same as the thickness of the first conductive layer 1321 of the terminals 132 and 133 to be described later.

The difference (T4-T3) between the thickness T4 of the terminals 132 and 133 and the thickness T3 of the third wiring 131C is, for example, 1 μm or more, preferably 5 μm or more, and for example, 50 μm or less, preferably 30 μm or less.

The width of the terminals 132 and 133 is, for example, 15 μm or more, preferably 40 μm or more, and for example, 500 μm or less, preferably 300 μm or less. The width of the terminals 132 and 133 is preferably larger than the width of the first wiring 131A, larger than the width of the second wiring 131B, and further, larger than the width of the third wiring 131C. The width of the terminals 132 and 133 indicates the maximum length in the width direction.

Each of the terminals 132 and 133 has the first conductive layer 1321, and the second conductive layer 1322 disposed on one surface in the thickness direction of the first conductive layer 1321. In the present embodiment, the terminals 132 and 133 consist of the seed layer (not shown), the first conductive layer 1311, and the second conductive layer 1312 disposed on one surface in the thickness direction of the first conductive layer 1311.

The first conductive layer 1321 of the terminals 132 and 133 is made of the same metal as the first conductive layer 1311 of the first wiring 131A described above and the first conductive layer 1311 of the third wiring 131C described above.

The first conductive layer 1321 of the terminals 132 and 133 is disposed at one side in the thickness direction of the insulating layer 12. The first conductive layer 1321 of the terminals 132 and 133 has the generally rectangular shape in the cross-sectional view.

The width of the first conductive layer 1321 of the terminals 132 and 133 is the same as the width (total width) of the terminals 132 and 133. The width of the first conductive layer 1321 of the terminals 132 and 133 is, for example, 15 μm or more, preferably 40 μm or more, and for example, 500 μm or less, preferably 300 μm or less.

The thickness of the first conductive layer 1321 of the terminals 132 and 133 is thinner than the thickness T4 of the terminals 132 and 133. The thickness of the first conductive layer 1321 of the terminals 132 and 133 is, for example, 1 μm or more, preferably 5 μm or more, and for example, 50 μm or less, preferably 30 μm or less.

The second conductive layer 1322 of the terminals 132 and 133 is made of the same metal as the second conductive layer 1312 of the second wiring 131B and the second conductive layer 1312 of the third wiring 131C described above.

The second conductive layer 1322 of the terminals 132 and 133 is disposed on one surface in the thickness direction of the first conductive layer 1321 of the terminals 132 and 133. In other words, the second conductive layer 1322 of the terminals 132 and 133 is in contact with one surface in the thickness direction of the first conductive layer 1321 of the terminals 132 and 133.

The width of the second conductive layer 1322 of the terminals 132 and 133 may be the same as the width (total width) of the terminals 132 and 133 or may be smaller than the width (total width) of the terminals 132 and 133. Preferably, the width of the second conductive layer 1322 of the terminals 132 and 133 is smaller than the width (total width) of the terminals 132 and 133. The width of the second conductive layer 1322 of the terminals 132 and 133 is, for example, 5 μm or more, preferably 10 μm or more, and for example, 100 μm or less, preferably 50 μm or less.

The thickness of the second conductive layer 1322 of the terminals 132 and 133 is thinner than the thickness T4 of the terminals 132 and 133. The thickness of the second conductive layer 1322 of the terminals 132 and 133 is, for example, 5 μm or more, preferably 10 μm or more, and for example, 100 μm or less, preferably 50 μm or less.

### 3. Method for Producing Wiring Circuit Board

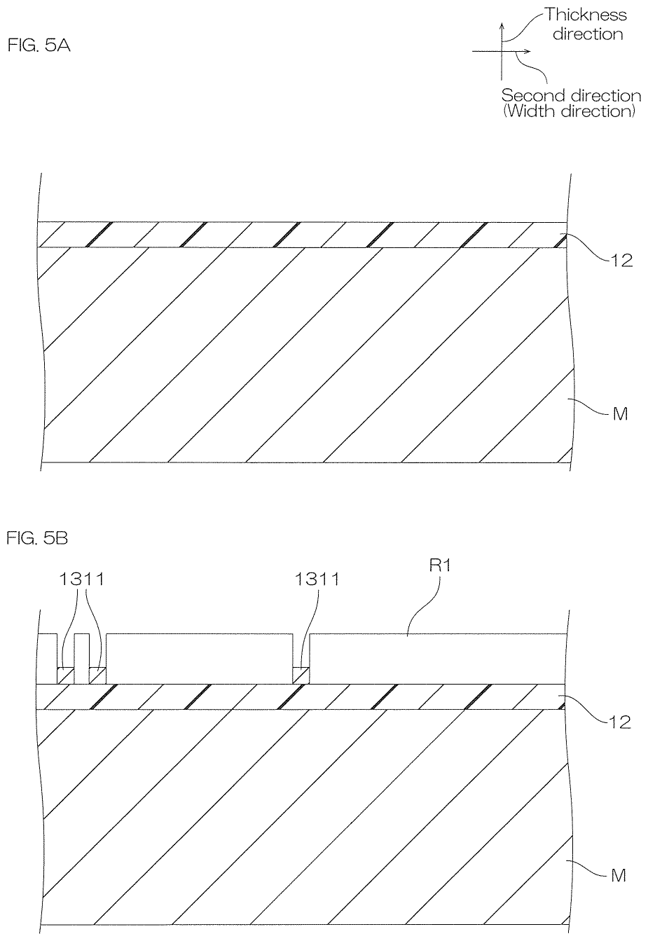

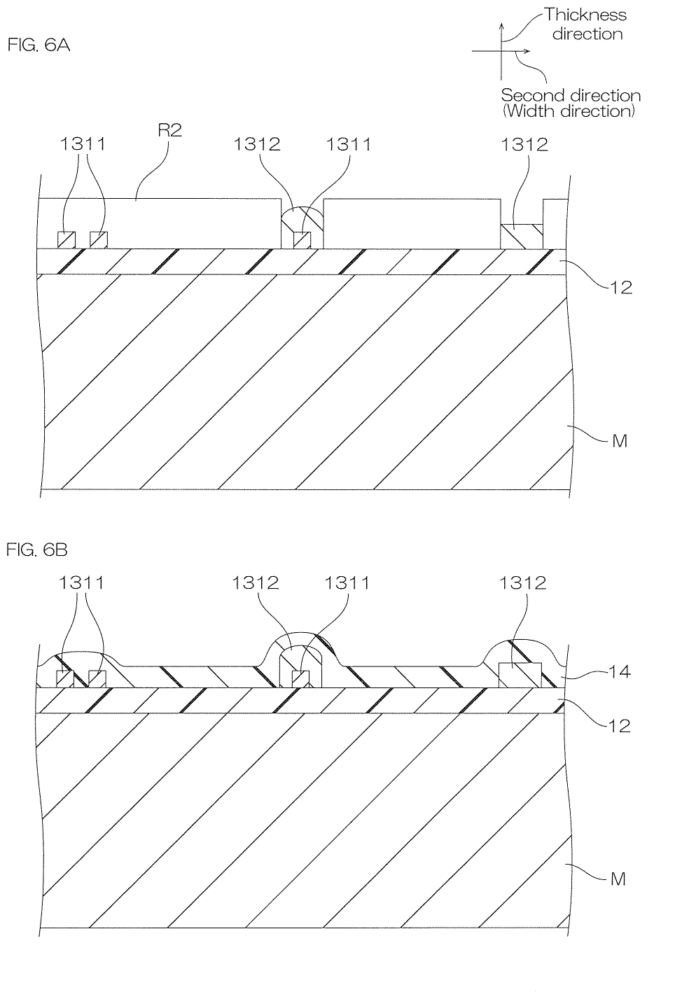

Next, a method for producing the wiring circuit board 1 is described with reference to FIGS. 5A to 6B.

A method for producing the wiring circuit board 1 includes an insulating layer forming step (ref: FIG. 5A), a first conductive layer forming step (ref: FIG. 5B), a second conductive layer forming step (ref: FIG. 6A), a cover insulating layer forming step (ref: FIG. 6B), and an etching step (not shown).

### (1) Insulating Layer Forming Step (Base Insulating Layer Forming Step)

As shown in FIG. 5A, in the insulating layer forming step, the insulating layer 12 (base insulating layer) is formed on one surface in the thickness direction of the metal support board 11. Specifically, as the material for the metal support board 11, a roll of a metal foil M is prepared. Next, a solution (varnish) of a photosensitive resin is coated onto the metal foil M drawn from the roll and dried. A coating film of the photosensitive resin is formed on the metal foil M by drying. Next, the coating film of the photosensitive resin is exposed to light. By exposing a portion of the photosensitive resin to be developed, the insulating layer 12 may be also formed into a predetermined pattern on the metal foil M.

### (2) First Conductive Layer Forming Step

Next, as shown in FIG. 5B, in the first conductive layer forming step, the first conductive layer 1311 of each of the first wiring 131A and the third wiring 131C and the first conductive layer 1321 of each of the terminals 132 and 133 (ref: FIG. 1) are formed on one surface in the thickness direction of the insulating layer 12.

Specifically, first, the seed layer (not shown) is formed on one surface in the thickness direction of the insulating layer 12. The seed layer is, for example, formed by sputtering. Examples of the material for the seed layer include chromium, copper, nickel, titanium, and alloys of these. When the insulating layer 12 is formed into the predetermined pattern, the seed layer may be also formed on one surface in the thickness direction of the insulating layer 12 and the metal foil M.

Next, a plating resist R1 is attached to one surface in the thickness direction of the seed layer, and the plating resist R1 is exposed to light in a state in which a portion where the first conductive layer 1311 of each of the first wiring 131A and the third wiring 131C and the first conductive layer 1321 of each of the terminals 132 and 133 are to be formed is shielded to light.

Next, the exposed plating resist R1 is developed. Then, the plating resist R1 of the shielded portion is removed, and the seed layer is exposed to the portion where the first conductive layer 1311 of each of the first wiring 131A and the third wiring 131C and the first conductive layer 1321 of each of the terminals 132 and 133 are to be formed. On the other hand, the plating resist R1 of the exposed portion remains.

Next, the first conductive layer 1311 of each of the first wiring 131A and the third wiring 131C and the first conductive layer 1321 of each of the terminals 132 and 133 are formed on the exposed seed layer by electrolytic plating.

After forming the first conductive layer 1311 of each of the first wiring 131A and the third wiring 131C and the first conductive layer 1321 of each of the terminals 132 and 133, the plating resist R1 is peeled.

### (3) Second Conductive Layer Forming Step

Next, as shown in FIG. 6A, in the second conductive layer forming step, the second conductive layer 1312 of the second wiring 131B is formed on one surface in the thickness direction of the insulating layer 12, and the second conductive layer 1312 of the third wiring 131C is formed on one surface in the thickness direction of the insulating layer 12 so as to cover the first wiring of the third wiring 131C, while the second conductive layer 1322 is formed on one surface in the thickness direction of each of the first conductive layers 1321 of the terminals 132 and 133.

Specifically, first, a plating resist R2 is attached so as to cover one surface in the thickness direction of the insulating layer 12 on which the seed layer is formed, and the first conductive layer 1311 and the first conductive layer 1321, and the plating resist R2 is exposed to light in a state in which a portion where the second conductive layer 1312 of each of the second wiring 131B and the third wiring 131C, and the second conductive layer 1322 of each of the terminals 132 and 133 are to be formed is shielded to light.

Next, the exposed plating resist R2 is developed. Then, the plating resist R2 of the shielded portion is removed, and at least one selected from the group consisting of the seed layer, the first conductive layer 1311, and the first conductive layer 1321 is exposed to a portion where the second conductive layer 1312 of each of the second wiring 131B and the third wiring 131C, and the second conductive layer 1322 of each of the terminals 132 and 133 are to be formed. On the other hand, the plating resist R2 of the exposed portion remains.

In the developed plating resist R2, the width of the portion where the second conductive layer 1312 of the third wiring 131C is to be formed is larger than the width of the first conductive layer 1311 of the third wiring 131C. Further, the first conductive layer 1311 of the third wiring 131C is, in the width direction, disposed in the central portion in the width direction of the portion where the second conductive layer 1312 of the third wiring 131C is to be formed. On the other hand, though not shown, the width of the portion where the second conductive layer 1322 of the terminals 132 and 133 is to be formed is the same as the width of the first conductive layer 1321 of the terminals 132 and 133 (when the shape of the terminals 132 and 133 in the cross-sectional view is generally the rectangular shape), or smaller than the width of the first conductive layer 1321 of the terminals 132 and 133 (when the shape of the terminals 132 and 133 in the cross-sectional view is generally the convex shape).

Next, by the electrolytic plating, the second conductive layer 1312 of the second wiring 131B is formed on one surface in the thickness direction of the exposed seed layer, and the second conductive layer 1312 of the third wiring 131C is formed on one surface in the thickness direction of the exposed seed layer and the first conductive layer 1311, while the second conductive layer 1322 of the terminals 132 and 133 is formed on one surface in the thickness direction of the first conductive layer 1321.

By forming the second conductive layer 1312 and the second conductive layer 1322, the first wiring 131A, the second wiring 131B, the third wiring 131C, and, and the terminals 132 and 133 are completed.

In the formation of the second conductive layer 1312 of the third wiring 131C, the plating grows from the seed layer disposed on one surface in the thickness direction of the insulating layer 12 in both end portions in the width direction of the third wiring 131C, while the plating grows from one surface in the thickness direction of the first conductive layer 1311 of the third wiring 131C in the central portion in the width direction of the third wiring 131C. Then, the second conductive layer 1312 is stacked on one surface in the thickness direction of the first conductive layer 1311 in the central portion in the width direction of the third wiring 131C. On the other hand, the second conductive layer 1312 is stacked at one side in the thickness direction of the insulating layer 12 in both end portions in the width direction of the third wiring 131C. Therefore, as described above, since the first conductive layer 1311 is disposed, the central portion in the width direction of the third wiring 131C protrudes toward one side in the thickness direction as compared with the end portion in the width direction of the third wiring 131C.

On the other hand, in the formation of the second conductive layer 1322 of the terminals 132 and 133, the plating uniformly grows from only one surface in the thickness direction of the first conductive layer 1321 of the terminals 132 and 133. Therefore, one surface in the thickness direction of the second conductive layer 1322 of the terminals 132 and 133 is flat. Further, since the growing of the plating is uniform, the thickness T4 of the terminals 132 and 133 is thicker than the thickness T3 of the third wiring 131C.

After completing the first wiring 131A, the second wiring 131B, the third wiring 131C, and the terminals 132 and 133, the plating resist R2 is peeled. Thereafter, the seed layer exposed by the peeling of the plating resist R2 is removed by etching.

### (4) Cover Insulating Layer Forming Step

Next, as shown in FIG. 6B, the cover insulating layer forming step, the cover insulating layer 14 is formed so as to cover one surface in the thickness direction of the insulating layer 12 and the conductive pattern 13. The cover insulating layer 14 is, for example, formed in the same manner as the above-described insulating layer 12.

### (5) Etching Step

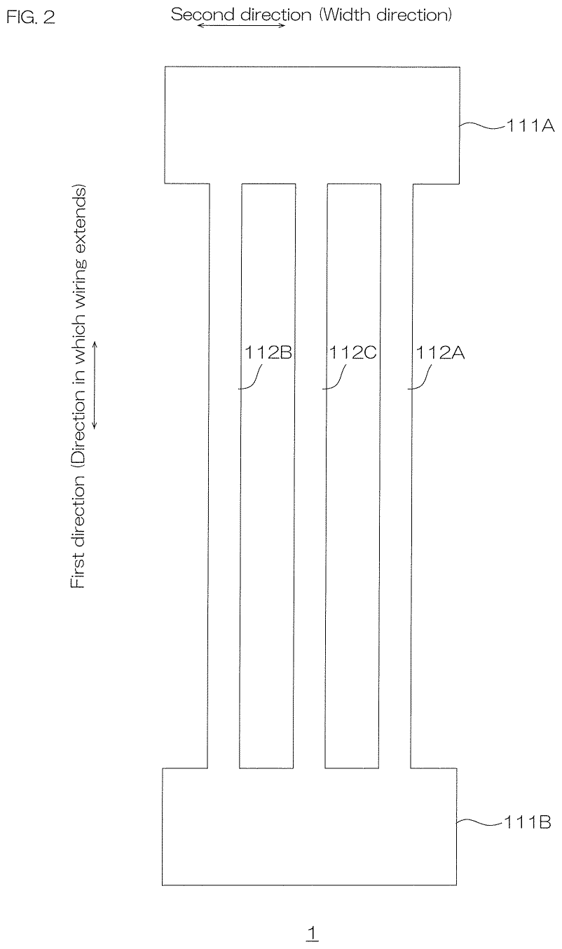

Next, in the etching step, by etching the metal foil M, the metal support board 11 shown in FIG. 2 is formed.

In this manner, the wiring circuit board 1 shown in FIG. 1 is produced.

### 4. Function and Effect

(1) According to the wiring circuit board 1, as shown in FIGS. 1 and 3, the wiring 131 includes the first wiring 131A, the second wiring 131B, and the third wiring 131C; the thickness T2 of the second wiring 131B is thicker than the thickness T1 of the first wiring 131A; and the thickness T3 of the third wiring 131C is thicker than the thickness T2 of the second wiring 131B. Therefore, it is possible to increase a degree of freedom in wiring design in the wiring circuit board 1.

(2) According to the wiring circuit board 1, as shown in FIG. 3, the third wiring 131C has the central portion and the end portion in the width direction, and the central portion protrudes toward one side in the thickness direction as compared with the end portion. Therefore, it is possible to increase the rigidity of the third wiring 131C in the thickness direction, while suppressing the increase in the rigidity of the third wiring 131C in the width direction. As a result, it is possible to increase the rigidity of the third wiring portion 3C in the thickness direction so as not to hinder the deformation of the third wiring portion 3C in the width direction. Further, since the wiring circuit board 1 includes the third wiring 131C having the relatively large wiring cross-sectional area, it is possible to reduce the electric resistivity.

(3) According to the wiring circuit board 1, as shown in FIG. 3, the first wiring 131A has the first conductive layer 1311, the second wiring 131B has the second conductive layer 1312, and the third wiring 131C has the first conductive layer 1311 and the second conductive layer 1312 covering the first conductive layer 1311. Therefore, by a simple step of forming two types of conductive layers of the first conductive layer 1311 and the second conductive layer 1312, it is possible to form three types of wirings having the different thicknesses (the first wiring 131A, the second wiring 131B, the third wiring 131C).

(4) According to the wiring circuit board 1, as shown in FIGS. 1 and 4, it further includes the terminals 132 and 133 connected to the wiring 131, and the thickness T4 of the terminals 132 and 133 is thicker than the thickness T3 of the third wiring 131C. Therefore, it is possible to furthermore increase the degree of freedom in design of the wiring circuit board in the wiring circuit board 1.

(5) According to the wiring circuit board 1, as shown in FIG. 4, the terminals 132 and 133 have the first conductive layer 1321, and the second conductive layer 1322 disposed on one surface in the thickness direction of the first conductive layer 1321. Therefore, by the simple step of forming the two types of conductive layers of the first conductive layer 1311 and the second conductive layer 1312, it is possible to further form the terminals 132 and 133 in addition to the three types of wirings having the different thicknesses (the first wiring 131A, the second wiring 131B, the third wiring 131C).

(5) According to the wiring circuit board 1, as shown in FIG. 4, the terminals 132 and 133 have the first conductive layer 1321, and the second conductive layer 1322 disposed on one surface in the thickness direction of the first conductive layer 1321. Therefore, by the simple step of forming the two types of conductive layers of the first conductive layer 1311 and the second conductive layer 1312, it is possible to furthermore form the terminals 132 and 133 in addition to the three types of wirings having the different thicknesses (the first wiring 131A, the second wiring 131B, the third wiring 131C).

### 5. Modified Examples

Next, modified examples are described. In each modified example, the same reference numerals are provided for members corresponding to each of those in the above-described embodiment, and their detailed description is omitted.

(1) In one embodiment of the wiring circuit board 1 described above, the terminal 132C and the terminal 133C are connected by the composite wiring consisting of the second wiring 131B and the third wiring 131C. However, the connection is not limited to this.

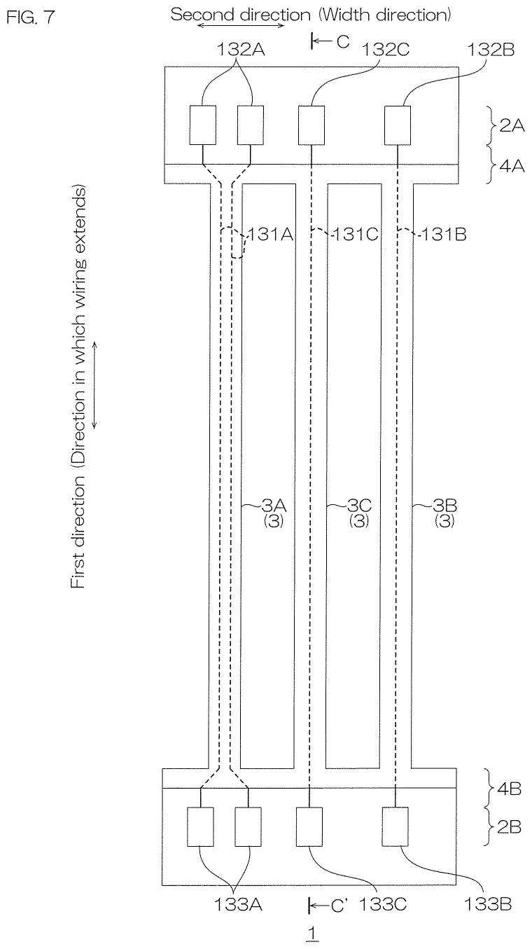

As shown in FIG. 7, the terminal 132C and the terminal 133C may be also connected by the third wiring 131C.

In the wiring circuit board 1 shown in FIG. 7, in each of the connecting portions 4A and 4B, the third wiring 131C is disposed between the terminal disposition portions 2A and 2B, and the third wiring portion 3C. That is, the single third wiring 131C is disposed continuously to the connecting portion 4A, the third wiring portion 3C, and the connecting portion 4B between the terminal 132C and the terminal 133C, and connects the terminal 132C to the terminal 133C. When the terminal 132C and the terminal 133C are connected by the single third wiring 131C, it is possible to furthermore reduce the electric resistivity.

That is, at least the third wiring 131C is disposed in each of the connecting portions 4A and 4B. More specifically, the first wiring 131A, the second wiring 131B, and the third wiring 131C are disposed in each of the connecting portions 4A and 4B.

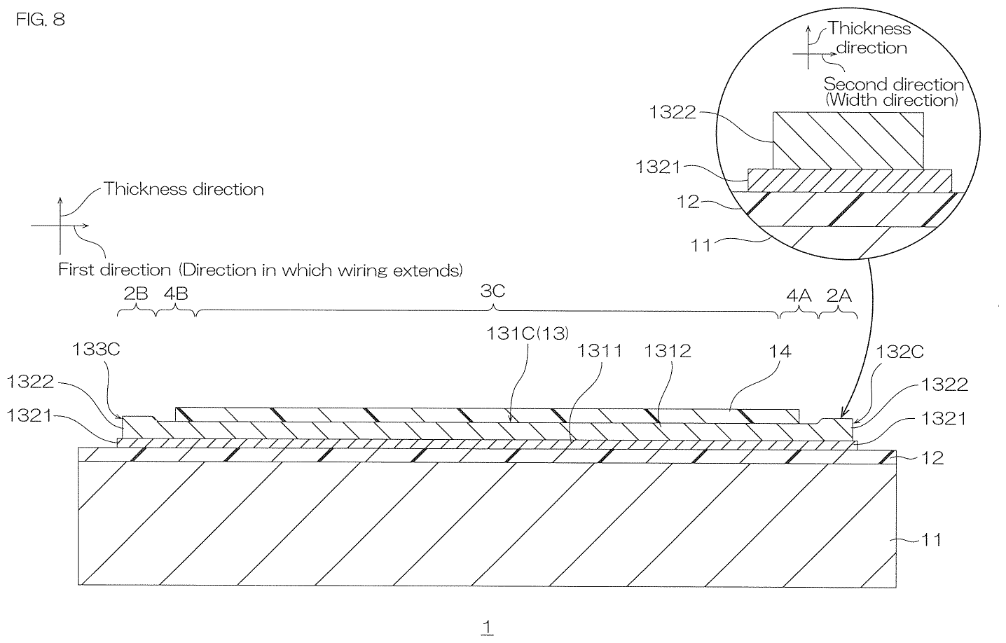

Further, as shown in FIG. 8, the first conductive layer 1311 of the third wiring 131C is continuous to the first conductive layer 1321 of the terminal 132C and the first conductive layer 1321 of the terminal 133C to be described later, and further, the second conductive layer 1312 of the third wiring 131C is continuous to the second conductive layer 1322 of the terminal 132C and the second conductive layer 1322 of the terminal 133C to be described later. The first conductive layer 1311 of the third wiring 131C is preferably made of the same metal as the first conductive layer 1321 of the terminal 132C and the first conducive layer 1321 of the terminal 133C, and the second conductive layer 1312 of the third wiring 131C is preferably made of the same metal as the second conductive layer 1322 of the terminal 132C and the second conductive layer 1322 of the terminal 133C.

(2) The above-described wiring circuit board 1 includes the first wiring portion 3A, the second wiring portion 3B, and the third wiring portion 3C. However, the arrangement of the wiring circuit board 1 is not limited to this.

In the wiring circuit board 1, the wiring 131 just has to include the first wiring 131A, the second wiring 131B, and the third wiring 131C. When the terminal 132C and the terminal 133C are connected by the composite wiring consisting of the second wiring 131B and the third wiring 131C, the wiring circuit board 1 may not include the second wiring portion 3B. That is, the wiring portion 3 may include at least the first wiring portion 3A in which the first wiring 131A is disposed, and the third wiring portion 3C in which the third wiring 131C is disposed.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICATION

A wiring circuit board of the present invention is available in connection of electronic components.

### DESCRIPTION OF REFERENCE NUMERALS

1 Wiring circuit board
2 Terminal disposition portion
3 Wiring portion
4 Connecting portion
11 Metal support board
12 Insulating layer (base insulating layer)
13 Conductive pattern
14 Cover insulating layer
131A First wiring
131B Second wiring
131C Third wiring

1. A wiring circuit board comprising:
a metal support board,
an insulating layer disposed on one surface in a thickness direction of the metal support board, and
a conductive pattern disposed on one surface in the thickness direction of the insulating layer,
wherein
the conductive pattern includes a wiring;
the wiring includes a first wiring, a second wiring, and a third wiring;
a thickness T2 of the second wiring is thicker than a thickness T1 of the first wiring; and
a thickness T3 of the third wiring is thicker than the thickness T2 of the second wiring.

2. The wiring circuit board according to claim 1, wherein
the third wiring has a central portion and an end portion in a width direction perpendicular to the thickness direction and a direction in which the wiring extends, and
the central portion protrudes toward one side in the thickness direction as compared with the end portion.

3. The wiring circuit board according to claim 1, wherein
the first wiring has a first conductive layer,
the second wiring has a second conductive layer, and
the third wiring has the first conductive layer and the second conductive layer covering the first conductive layer.

4. The wiring circuit board according to claim 1, wherein
the conductive pattern further includes a terminal connected to the wiring.

5. The wiring circuit board according to claim 4, wherein
a thickness T4 of the terminal is thicker than the thickness T3 of the third wiring.

6. The wiring circuit board according to claim 4, wherein
the terminal has the first conductive layer and the second conductive layer disposed on one surface in the thickness direction of the first conductive layer.

7. The wiring circuit board according to claim 4 comprising:
a terminal disposition portion in which the terminal is disposed; a wiring portion in which at least one selected from the group consisting of the first wiring, the second wiring, and the third wiring is disposed; and
a connecting portion connecting the terminal disposition portion to the wiring portion, wherein
at least one selected from the group consisting of the first wiring, the second wiring, and the third wiring is disposed in the connecting portion.

8. The wiring circuit board according to claim 7, wherein
at least the third wiring is disposed in the connecting portion.

9. The wiring circuit board according to claim 7, wherein
the wiring portion includes at least a first wiring portion in which the first wiring is disposed and a third wiring portion in which the third wiring is disposed, and
the first wiring portion and the third wiring portion are spaced from each other in the width direction perpendicular to the thickness direction and the direction in which the wiring extends.
